(19) United States
(12) Patent Application Publication
(10) Pub. No.: US 2026/0090464 A1
(43) Pub. Date: Mar. 26, 2026

(54) ALIGNMENT MARK USED IN WAFER BONDING PROCESS AND WAFER BONDING METHOD USING THE SAME

(71) Applicant: AUROS TECHNOLOGY, INC., Hwaseong-si (KR)

(72) Inventors: Chang Ho LEE, Hwaseong-si (KR); Hyun Jin CHANG, Hwaseong-si (KR); Hyun Chul LEE, Hwaseong-si (KR)

(21) Appl. No.: 19/408,311

(22) Filed: Dec. 3, 2025

Related U.S. Application Data
(63) Continuation of application No. PCT/KR2024/011020, filed on Jul. 29, 2024.

(30) Foreign Application Priority Data
Nov. 13, 2023 (KR) 10-2023-0156184

(51) Int. Cl. H10W 80/00

(52) U.S. Cl. CPC H10W 80/163; H10W 46/301

(57) ABSTRACT

Disclosed are an alignment mark used for aligning a first semiconductor wafer and a second semiconductor wafer in a wafer bonding process in which the first semiconductor wafer and a flipped second semiconductor wafer are aligned and bonded such that the surfaces on which semiconductor elements are formed face each other, and to a wafer bonding method using the same. The alignment mark includes a first alignment mark formed in a predetermined region of the first semiconductor wafer and having a first center of symmetry and a second alignment mark formed in a predetermined region of the second semiconductor wafer and having a second center of symmetry, the second alignment mark being configured to overlap the first alignment mark in a flipped state when the first semiconductor wafer and the flipped second semiconductor wafer are bonded.

### TECHNICAL FIELD

The present disclosure relates to an alignment mark used for aligning a first semiconductor wafer and a second semiconductor wafer in a wafer bonding process in which the first semiconductor wafer and a flipped second semiconductor wafer are aligned and bonded such that the surfaces on which semiconductor elements are formed face each other, and to a wafer bonding method using the same.

### BACKGROUND ART

The integration of semiconductor elements had been conventionally achieved through the miniaturization of patterns on the XY plane in the past, but recently, the semiconductor integration has been accomplished by stacking patterns in a direction of the Z-axis.

In addition, the semiconductor integration has been achieved by employing wafer bonding technology in which two semiconductor wafers having semiconductor elements formed thereon are bonded together into one. For example, a method has been used in which a semiconductor wafer having memory devices formed thereon is bonded to a semiconductor wafer having logic devices formed thereon and the pads of the memory devices is electrically connected to the pads of the logic devices.

At this time, when misalignment occurs between semiconductor wafers, there is a problem in that the pads of the memory devices and the pads of the logic devices are not electrically connected to each other.

To solve such a problem, a method has been employed in which alignment marks are respectively formed on semiconductor wafers and the semiconductor wafers are aligned using these alignment marks.

For example, U.S. Patent Application Publication No. US 2023/0135060 A1 discloses a method of aligning a first wafer and a second wafer by aligning a first alignment mark on the first wafer and a second alignment mark on the second wafer.

### Related Art Documents

(Patent Document 1) U.S. Patent Application Publication No. US 2023/0135060 A1

### DISCLOSURE

### Technical Problem

An objective of the present disclosure is to provide a new alignment mark used in a wafer bonding process.

### Technical Solution

In order to achieve the above-described objective, the present disclosure provides an alignment mark used in a wafer bonding process in which a first semiconductor wafer and a flipped second semiconductor wafer are aligned and bonded together, which includes a first alignment mark formed in a predetermined region of the first semiconductor wafer and having a first center of symmetry and a second alignment mark formed in a predetermined region of the second semiconductor wafer and having a second center of symmetry, the second alignment mark being configured to overlap the first alignment mark in a flipped state when the first semiconductor wafer and the flipped second semiconductor wafer are bonded.

Herein, the first center of symmetry and the second center of symmetry overlap when the first semiconductor wafer and the flipped second semiconductor wafer are aligned, and a difference between the first center of symmetry and the second center of symmetry represents an alignment error between the first semiconductor wafer and the flipped second semiconductor wafer.

Also, the first alignment mark is rotationally symmetrical at 90 degrees and 180 degrees with respect to the first center of symmetry, and is asymmetrical with respect to a first axis passing through the first center of symmetry.

The first alignment mark and the second alignment mark have the same shape and size.

In addition, the first alignment mark includes a first alignment mark element and a third alignment mark element respectively formed in two quadrants arranged diagonally among the quadrants, and a second alignment mark element and a fourth alignment mark element respectively formed in the remaining two quadrants.

The first alignment mark element includes at least a first bar extending in a direction of the second axis direction, the second alignment mark element includes at least a second bar extending in a direction of the first axis direction, the third alignment mark element includes at least a third bar extending in a direction of the second axis direction, and the fourth alignment mark element includes at least a fourth bar extending in a direction of the first axis direction.

In addition, the second alignment mark includes a fifth bar, a sixth bar, a seventh bar, and an eighth bar respectively corresponding to the first bar, the second bar, the third bar, and the fourth bar of the first alignment mark, and the bar of the first alignment mark and the bar of the flipped second alignment mark that belong to the same quadrant are perpendicular to each other.

In addition, the bar of the first alignment mark and the bar of the flipped second alignment mark that belong to the same quadrant are orthogonal to each other.

In addition, as a wafer bonding method for aligning and bonding a first semiconductor wafer and a flipped second semiconductor wafer, the present disclosure provides a wafer bonding method that includes forming a first alignment mark having a first center of symmetry in a predetermined region of the first semiconductor wafer, forming a second alignment mark having a second center of symmetry in a predetermined region of the second semiconductor wafer so as to overlap the first alignment mark in a flipped state when the first semiconductor wafer and the flipped second semiconductor wafer are bonded, aligning the first alignment mark and the second alignment mark, and bonding the first semiconductor wafer and the second semiconductor wafer.

Herein, the first center of symmetry and the second center of symmetry overlap when the first semiconductor wafer and the flipped second semiconductor wafer are aligned, and a difference between the first center of symmetry and the second center of symmetry represents an alignment error between the first semiconductor wafer and the flipped second semiconductor wafer.

Also, the first alignment mark is rotationally symmetrical at 90 degrees and 180 degrees with respect to the first center of symmetry, and is asymmetrical with respect to a first axis passing through the first center of symmetry.

The first alignment mark and the second alignment mark have the same shape and size.

### Advantageous Effects

The alignment mark according to the present disclosure may have the same shape for the first alignment mark and the second alignment mark formed on the first semiconductor wafer and the second semiconductor wafer, respectively. Accordingly, it is possible to maximally exclude the influence caused by an exposure process for forming the first alignment mark and the second alignment mark. In addition, it is possible to minimize the influence caused by an optical measurement device for measuring an alignment error.

### DESCRIPTION OF DRAWINGS

FIG. 1 is a view illustrating a first semiconductor wafer on which a first alignment mark is formed.

FIG. 2 is a view illustrating a second semiconductor wafer on which a second alignment mark is formed.

FIG. 3 is a view illustrating a method of checking an alignment error between a first semiconductor wafer and a flipped second semiconductor wafer.

FIG. 4 is a view illustrating an example of a first alignment mark shown in FIG. 1.

FIG. 5 is a view illustrating an example of a second alignment mark shown in FIG. 2.

FIG. 6 is a view illustrating a flipped second alignment mark.

FIG. 7 is a view illustrating an example of an alignment mark image.

FIG. 8 is a view illustrating a method of measuring an alignment error.

FIG. 9 is a view illustrating another example of a first alignment mark and a second alignment mark.

FIG. 10 is a view illustrating an alignment mark image in which a first alignment mark and a flipped second alignment mark of FIG. 9 overlap.

### MODE FOR INVENTION

Hereinafter, exemplary embodiments of the present disclosure will be described in detail with reference to the accompanying drawings. However, the exemplary embodiments of the present disclosure may be modified in various different forms, and the scope of the present disclosure should not be construed as being limited to the exemplary embodiments described below. The exemplary embodiments of the present disclosure may be provided to more completely explain the present disclosure to those of ordinary skill in the art. Accordingly, the shape of the elements in the drawings may be exaggerated to emphasize a clearer description, and the elements denoted by the same reference numerals in the drawings may represent the same elements.

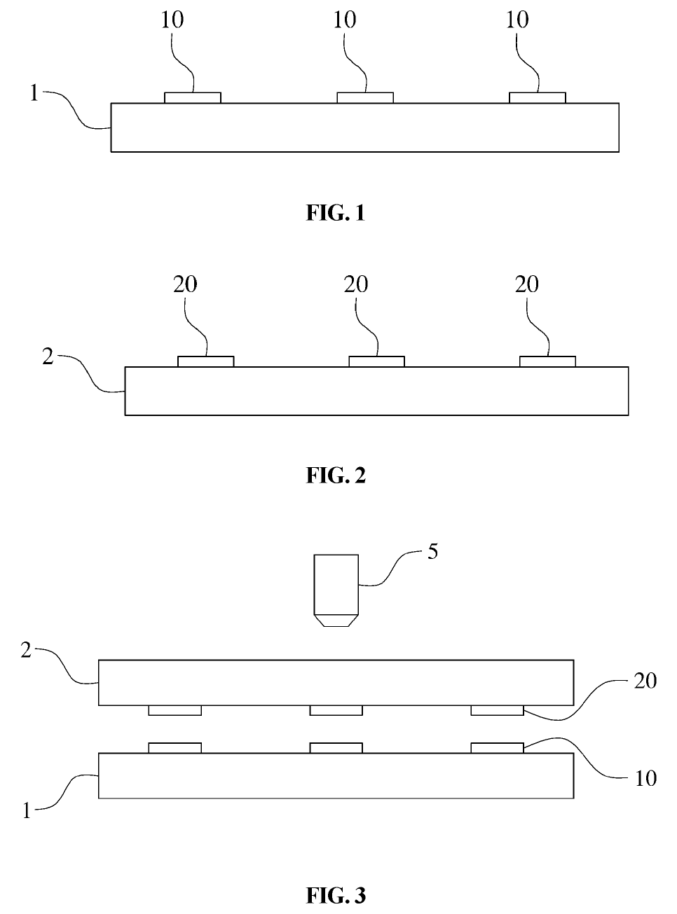

FIG. 1 is a view illustrating a first semiconductor wafer on which a first alignment mark is formed, and FIG. 2 is a view illustrating a second semiconductor wafer on which a second alignment mark is formed.

A first semiconductor wafer 1 and a second semiconductor wafer 2 may include a silicon wafer and a plurality of patterned layers for forming semiconductor devices. Wafers other than silicon wafers may also be used.

As shown in FIG. 1, a first alignment mark 10 may be formed in a predetermined region of the first semiconductor wafer 1. A plurality of first alignment marks 10 may be formed on the first semiconductor wafer 1.

As shown in FIG. 2, a second alignment mark 20 may be formed in a predetermined region of the second semiconductor wafer 2. A plurality of second alignment marks 20 may be formed on the second semiconductor wafer 2.

The second alignment marks 20 may be disposed so as to overlap the corresponding first alignment marks 10 when the first semiconductor wafer 1 and the flipped second semiconductor wafer 2 are bonded together. For example, the second alignment mark 20 at the center of FIG. 2 may overlap the first alignment mark 10 at the center of FIG. 1, the second alignment mark 20 on the left of FIG. 2 may overlap the first alignment mark 10 on the left of FIG. 1, and the second alignment mark 20 on the right of FIG. 2 may overlap the first alignment mark 10 on the right of FIG. 1.

In addition, when the second semiconductor wafer 2 is flipped so that the left and right sides are reversed in the drawing, the second alignment mark 20 on the left of FIG. 2 may overlap the first alignment mark 10 on the right of FIG. 1, and the second alignment mark 20 on the right of FIG. 2 may overlap the first alignment mark 10 on the left of FIG. 1.

In FIGS. 1 and 2, the first alignment mark 10 and the second alignment mark 20 may be illustrated as being formed on the topmost layer and exposed to the outside, but other layers may be formed over the first alignment mark 10 and the second alignment mark 20.

FIG. 3 is a view illustrating a method of acquiring an alignment mark image.

As shown in FIG. 3, the alignment mark image including both the first alignment mark 10 and the flipped second alignment mark 20 may be acquired by capturing, at once, the overlapped first alignment mark 10 and second alignment mark 20 using a camera 5. The acquired alignment mark image may then be analyzed to check the alignment error. The illumination used for imaging may have high reflectance with respect to the first alignment mark 10 and the second alignment mark 20, low reflectance with respect to the second semiconductor wafer 2, and high transmittance. For example, when a silicon wafer is used as the second semiconductor wafer 2, it is preferable that the wavelength band of the illumination fall within the range of 900 nm to 2000 nm. This is because, although there is a difference depending on the thickness of the silicon wafer, an edge region of light transmittance may be formed where the transmittance rapidly changes (increases) from about 900 nm.

When the first alignment mark 10 is embedded in the first semiconductor wafer 1, the illumination may also have high transmittance with respect to the first semiconductor wafer 1. The illumination may pass through the second semiconductor wafer 2 and then be reflected from the second alignment mark 20 and the first alignment mark 10.

As shown in FIG. 3, the alignment mark image may be acquired during an alignment process, or may be acquired after the bonding of the first semiconductor wafer 1 and the second semiconductor wafer 2 is completed. When acquired during the alignment process, the measured alignment error may be used to align the first semiconductor wafer 1 and the second semiconductor wafer 2. When acquired after the bonding is completed, the measured alignment error may be used to determine whether the bonded wafer is defective.

The first semiconductor wafer 1 and the second semiconductor wafer 2 may be fixed to a stage, table, vacuum chuck, etc. that can move in the X, Y, and Z directions, so that the plane movement for alignment and the distance adjustment between the first semiconductor wafer 1 and the second semiconductor wafer 2 for bonding may be possible.

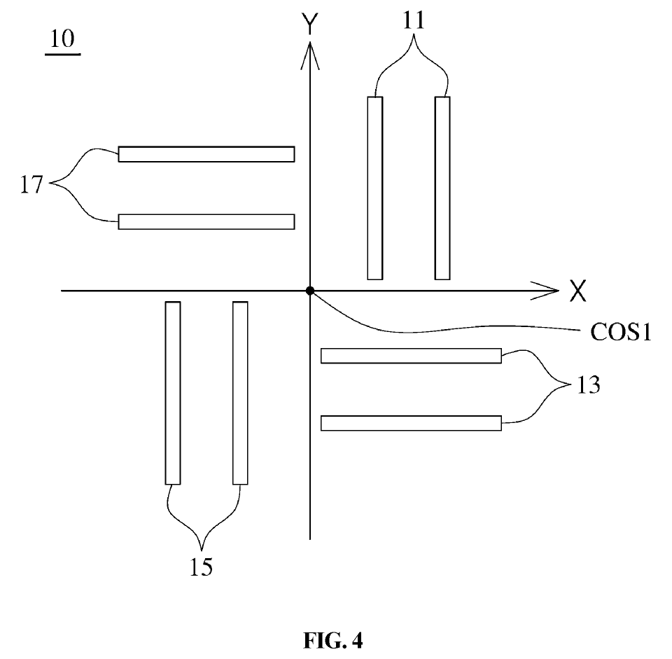

FIG. 4 is a view illustrating an example of a first alignment mark shown in FIG. 1. FIG. 4 illustrates the first alignment mark 10 as viewed from above the first semiconductor wafer 1.

As shown in FIG. 4, the first alignment mark 10 may be rotationally symmetrical at 90 degrees and 180 degrees with respect to the first center of symmetry (COS1). However, it may be asymmetrical with respect to the first axis (X-axis or Y-axis in FIG. 4) passing through the first center of symmetry (COS1). In addition, it may also be asymmetrical with respect to the second axis orthogonal to the first axis. Hereinafter, it will be described that the X axis is the first axis.

The first alignment mark 10 may include a first alignment mark element 11, a second alignment mark element 13, a third alignment mark element 15, and a fourth alignment mark element 17.

The first alignment mark element 11 and the third alignment mark element 15 may be arranged in the first quadrant and the third quadrant, respectively, and the second alignment mark element 13 and the fourth alignment mark element 17 may be arranged in the second quadrant and the fourth quadrant, respectively.

The first alignment mark element 11 may include at least a first bar extending in a direction of the Y-axis direction. When a plurality of first bars is included, the first bars may be arranged to be spaced apart from each other along the X-axis direction. Although two first bars are illustrated, three or more bars may also be provided.

The second alignment mark element 13 may include at least a second bar extending in a direction of the X-axis direction. When a plurality of second bars is included, the second bars may be arranged to be spaced apart from each other along the X-axis direction. Although two second bars are illustrated, three or more bars may also be provided.

Like the first alignment mark element 11, the third alignment mark element 15 may include at least a third bar extending in a direction of the Y-axis direction.

Like the second alignment mark element 13, the fourth alignment mark element 17 may include at least a fourth bar extending in a direction of the X-axis direction.

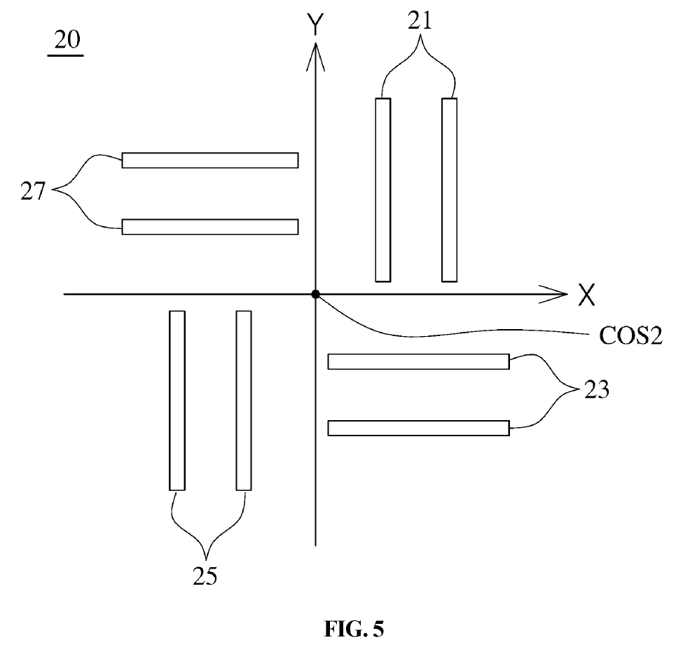

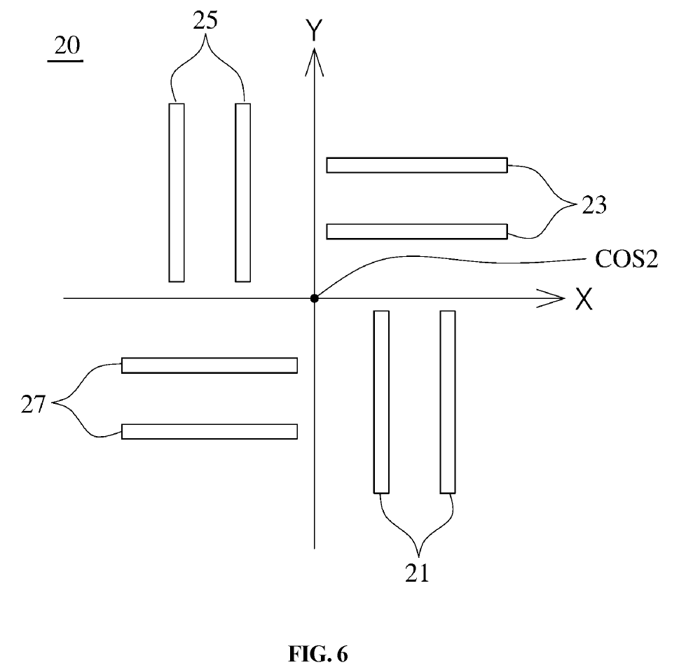

FIG. 5 is a view illustrating an example of a second alignment mark shown in FIG. 2. FIG. 5 illustrates the second alignment mark 20 as viewed from above the second semiconductor wafer 2. FIG. 6 illustrates the second alignment mark 20 flipped so that the top and bottom are reversed.

As shown in FIG. 5, the second alignment mark 20 may be completely identical in shape and size to the first alignment mark 10. Accordingly, the influence of an exposure process for forming the first alignment mark 10 and the second alignment mark 20 can be excluded as much as possible. In addition, it is possible to minimize the influence of the optical measurement device for measuring the alignment error. For example, not only are the pattern shapes of each layer consistent with one another, but the patterns are uniformly distributed in the same region, thereby minimizing measurement distortion due to aberrations caused by the optical measurement device.

The second alignment mark 20 may include a fifth alignment mark element 21, a sixth alignment mark element 23, a seventh alignment mark element 25, and an eighth alignment mark element 27, which are formed of bars arranged in each quadrant, similar to the first alignment mark 10.

The second alignment mark 20 may not be symmetrical with respect to the X-axis or Y-axis, like the first alignment mark 10. Accordingly, as shown in FIG. 6, the flipped second alignment mark 20 may have a shape different from that of the first alignment mark 10. That is, it may be a shape that is flipped left and right or up and down on the basis of the shape on the plane.

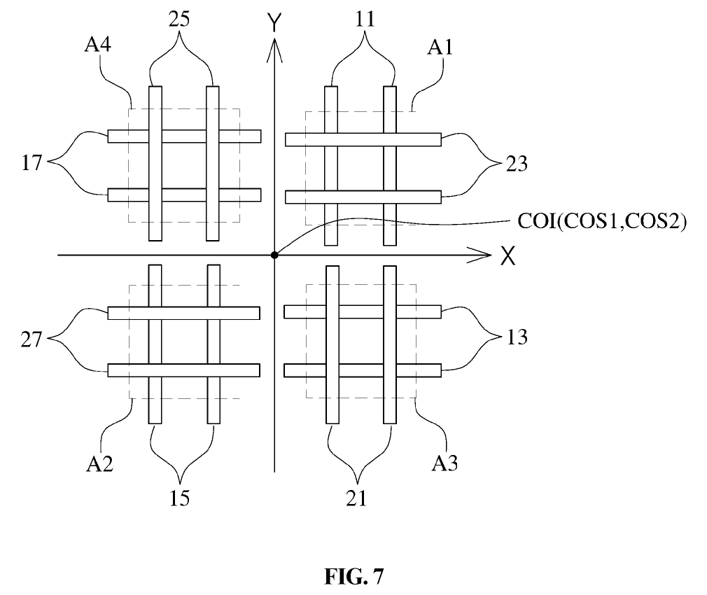

FIG. 7 is a view illustrating an example of an alignment mark image. As shown in FIG. 7, an alignment mark image can be acquired in which the first alignment mark 10 and the flipped second alignment mark 20 overlap. The alignment mark image shown in FIG. 7 may represent a state in which the first alignment mark 10 of FIG. 4 and the second alignment mark 20 of FIG. 6 overlap.

The COI in FIG. 7 may indicate the center of the alignment mark image. The center (COI) of the alignment mark image can be determined in various ways. For example, the center of rotation symmetry at which the alignment mark image and the image acquired by rotating the alignment mark image by 180 degrees are the same may be identified as the center (COI) of the alignment mark image.

In FIG. 7, for convenience, the center of symmetry (COS1) of the first alignment mark 10, the center of symmetry (COS2) of the second alignment mark 20, and the center (COI) of the alignment mark image are all illustrated as coinciding with one another. However, when there is the alignment error, the center of symmetry (COS1) of the first alignment mark 10 and the center (COS2) of symmetry of the second alignment mark 20 may not coincide with each other. Also, regardless of the presence or absence of alignment error, the center (COI) of the alignment mark image may be different from the center of symmetry (COS1) of the first alignment mark 10 and the center of symmetry (COS2) of the second alignment mark 20.

The alignment error between the first semiconductor wafer 1 and the flipped second semiconductor wafer 2 may be measured by a method of measuring the offset between the center of symmetry (COS1) of the first alignment mark 10 and the center of symmetry (COS2) of the second alignment mark 20.

When the alignment error between the first semiconductor wafer 1 and the inverted second semiconductor wafer 2 is 0 (zero), the center of symmetry (COS1) of the first alignment mark 10 and the center of symmetry (COS2) of the second alignment mark 20 may coincide with each other. The difference between the center of symmetry (COS1) of the first alignment mark 10 and the center of symmetry (COS2) of the second alignment mark 20 may indicate the alignment error between the first semiconductor wafer 1 and the flipped second semiconductor wafer 2.

Hereinafter, a method of measuring an alignment error in the X-axis direction will be described with reference to the alignment mark image shown in FIG. 7.

A method of measuring the alignment error may include the following steps.

First, a difference between the X value of the center of symmetry (COS1) of the first alignment mark 10 and the X value of the center (COI) of the acquired alignment mark image may be acquired (S11).

As shown in FIG. 7, a region (A₁) in the first quadrant of the acquired alignment mark image may be selected, and a region (A₂) that is 180 degrees symmetrical with respect to the center (COI) of the acquired alignment mark image may be selected. This region (A₂) may be approximately located in the third quadrant.

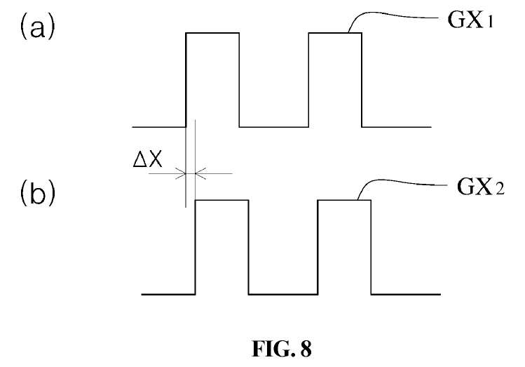

Next, the two-dimensional images of the two selected regions (A₁, A₂) may be each projected into one dimension. That is, the gray values of pixels having the same X value in the two-dimensional image may be all added, the average of the gray values may be calculated, or the gray values may be normalized. Then, graphs (G_{X1}, G_{X2}) representing the change in the gray values according to the X value can be drawn, respectively as shown in (a) and (b) of FIG. 8. In this case, the graph (G_{X2}) representing the A₂ region may be a graph acquired by projecting the two-dimensional image of the A₂ region and then flipping it left and right.

Since the gray value of the first bars 11 is different from the gray value of the space between the first bars 11, the graph (G_{X1}) in which peaks appear at the positions of the first bars 11 can be acquired as shown in (a) of FIG. 8. Since the influence by the sixth bars (23, the horizontal bars) is the same according to the X value, the influence by the sixth bar 23 may be almost negligible. In the graph (G_{X2}) of (b) of FIG. 8, the influence by the eighth bar 27 may be almost ignored for the same reason.

When the X value of the center of symmetry (COS1) of the first alignment mark 10 and the X value of the center (COI) of the acquired alignment mark image are the same, the two graphs (G_{X1}, G_{X2}) should almost coincide with each other.

When the X value of the center of symmetry (COI1) of the first alignment mark 10 is not the same as the X value of the center (COI) of the acquired alignment mark image, the positions of the peak values of the two graphs (G_{X1,} G_{X2}) may be offset. Also, this offset value (ΔX) may represent the difference between the X value of the center of symmetry (COI1) of the first alignment mark 10 and the X value of the center (COI) of the acquired alignment mark image.

Next, the difference between the X value of the center of symmetry (COS2) of the second alignment mark 20 and the X value of the center (COI) of the acquired alignment mark image may be acquired. In this step, a region (A₃) in the second quadrant of the acquired alignment mark image may be selected, and a region (A₄) that is 180-degree symmetrical with respect to the center (COI) of the alignment mark image may be selected. This region (A₄) may be located in the fourth quadrant. Then, graphs representing the two selected regions (A_{2,} A₄) may be plotted, and these graphs may be used to acquire the difference between the X value of the center of symmetry (COS2) of the second alignment mark 20 and the X value of the center (COI) of the acquired alignment mark image.

Next, the alignment error value in the X-axis direction may be acquired by using the difference between the X value of the center of symmetry (COS1) of the first alignment mark 10 and the X value of the center (COI) of the acquired alignment mark image, and the difference between the X value of the center of symmetry (COS2) of the second alignment mark 20 and the X value of the center (COI) of the acquired alignment mark image.

By changing only the projection direction, the difference between the Y value of the center of symmetry (COS1) of the first alignment mark 10 and the Y value of the center of symmetry (COI) of the acquired alignment mark image and the difference between the Y value of the center of symmetry (COS1) of the second alignment mark 20 and the Y value of the center of symmetry (COI) of the acquired alignment mark image can be acquired in the same way, and using this, the alignment error value in the Y-axis direction can be acquired.

Hereinafter, a wafer bonding method for aligning and bonding the first semiconductor wafer 1 and the flipped second semiconductor wafer 2 using the above-described alignment marks will be described.

First, as shown in FIGS. 1 and 2, the first alignment mark 10 and the second alignment mark 20 may be respectively formed in predetermined regions of the first semiconductor wafer 1 and the second semiconductor wafer 2.

The second alignment mark 20 may be formed in a predetermined region of the second semiconductor wafer 2 so as to overlap the first alignment mark 10 in the flipped state when the first semiconductor wafer 1 and the flipped second semiconductor wafer 2 are bonded.

Next, as shown in FIG. 3, the first semiconductor wafer 1 and the second semiconductor wafer 2 may be temporarily aligned so that the surfaces on which the semiconductor elements of the first semiconductor wafer 1 and the second semiconductor wafer 2 are formed face each other. In this step, the coordinates of the first alignment mark 10 and the coordinates of the second alignment mark 20 may be individually measured, and temporary alignment can be performed using these coordinates.

Next, an alignment mark image in which the first alignment mark 10 and the second alignment mark 20 overlap (for example, the image shown in FIG. 7) may be acquired using the camera 5.

Also, by analyzing the alignment mark image, the alignment error between the first center of symmetry (COS1) of the first alignment mark 10 and the second center of symmetry (COS2) of the second alignment mark 20 may be calculated.

Thereafter, using this alignment error, the first alignment mark 10 and the second alignment mark 20 may be aligned. When the first center of symmetry (COS1) and the second center of symmetry (COS2) overlap (i.e., when the alignment error is zero), the first alignment mark 10 and the second alignment mark 20 may be considered to be aligned. When the first alignment mark 10 and the second alignment mark 20 are aligned, the first semiconductor wafer 1 and the second semiconductor wafer 2 may also be aligned.

Next, the first aligned semiconductor wafer 1 and the second semiconductor wafer 2 may be bonded.

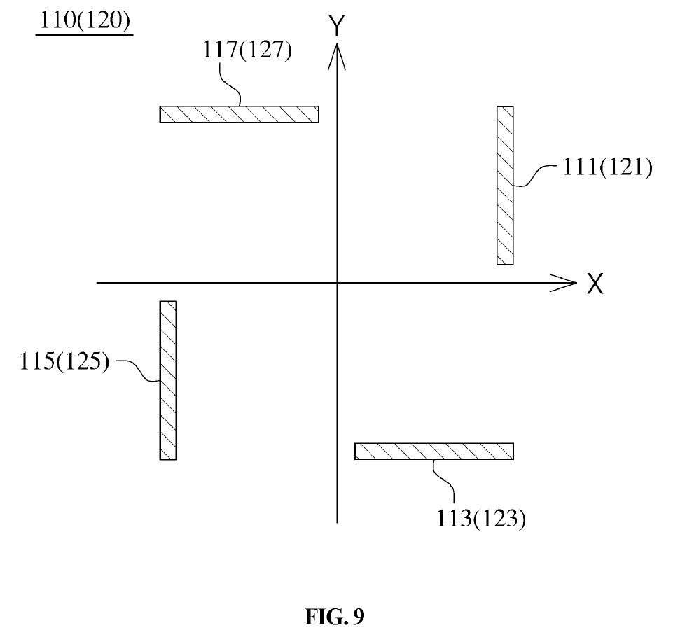

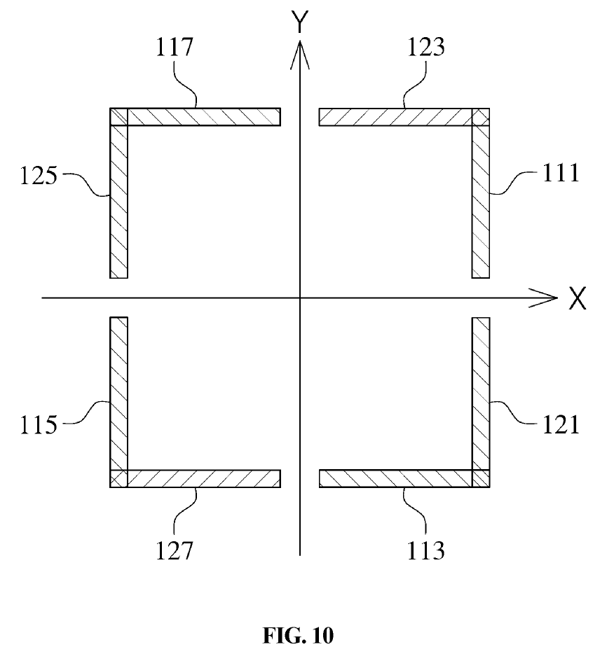

FIG. 9 is a view illustrating another example of a first alignment mark and a second alignment mark, and FIG. 10 is a view illustrating an alignment mark image in which a first alignment mark and a flipped second alignment mark of FIG. 9 overlap.

The alignment mark shown in FIG. 10 may be different from the alignment mark shown in FIG. 7 at positions where the bars 111, 113, 115, 117 constituting the first alignment mark 110 and the bars 121, 123, 125, 127 constituting the second alignment mark 120 intersect. In the alignment mark shown in FIG. 10, the bars 111, 113, 115, 117 constituting the first alignment mark 110 and the bars 121, 123, 125, 127 constituting the second alignment mark 120 may together form an approximate rectangular shape. The bars 111, 113, 115, 117 constituting the first alignment mark 110 and the bars 121, 123, 125, 127 constituting the second alignment mark 120 may overlap each other at the corner regions of the rectangle.

The exemplary embodiments described above may be merely illustrative of the preferred exemplary embodiments of the present disclosure, and the scope of the present disclosure may not be limited to the described exemplary embodiments, and various changes, modifications, or substitutions may be made by those skilled in the art within the technical spirit of the present disclosure and the claims, and it should be understood that such exemplary embodiments fall within the scope of the present disclosure.

### DESCRIPTION OF REFERENCE NUMERALS

1: first semiconductor wafer

2: second semiconductor wafer

5: camera

10, 110: first alignment mark

11: first alignment mark element

13: second alignment mark element

15: third alignment mark element

17: fourth alignment mark element

20, 120: second alignment mark

21: fifth alignment mark element

23: sixth alignment mark element

25: seventh alignment mark element

27: eighth alignment mark element

1. An alignment mark used in a wafer bonding process for aligning and bonding a first semiconductor wafer and a flipped second semiconductor wafer, the mark comprising:
a first alignment mark formed in a predetermined region of the first semiconductor wafer and having a first center of symmetry; and
a second alignment mark formed in a predetermined region of the second semiconductor wafer and having a second center of symmetry, the second alignment mark being configured to overlap the first alignment mark in a flipped state when the first semiconductor wafer and the flipped second semiconductor wafer are bonded,
wherein the first center of symmetry and the second center of symmetry overlap when the first semiconductor wafer and the flipped second semiconductor wafer are aligned,
a difference between the first center of symmetry and the second center of symmetry represents an alignment error between the first semiconductor wafer and the flipped second semiconductor wafer,
the first alignment mark is rotationally symmetrical at 90 degrees and 180 degrees with respect to the first center of symmetry, and is asymmetrical with respect to a first axis passing through the first center of symmetry,
the first alignment mark and the second alignment mark have the same shape and size,
the first alignment mark and the second alignment mark comprises a plurality of bars, and
a bar of the first alignment mark and a bar of the flipped second alignment mark, which belong to the same quadrant among quadrants divided by the first axis and a second axis orthogonal to the first axis, are perpendicular to each other.

2. The mark of claim 1, wherein the first alignment mark comprises a first alignment mark element and a third alignment mark element respectively formed in two quadrants arranged diagonally among the quadrants, and a second alignment mark element and a fourth alignment mark element respectively formed in the remaining two quadrants,
the first alignment mark element comprises at least a first bar extending in a direction of the second axis direction,
the second alignment mark element comprises at least a second bar extending in a direction of the first axis direction,
the third alignment mark element comprises at least a third bar extending in a direction of the second axis direction, and
the fourth alignment mark element comprises at least a fourth bar extending in a direction of the first axis direction.

3. The mark of claim 2, wherein the second alignment mark comprises a fifth bar, a sixth bar, a seventh bar, and an eighth bar respectively corresponding to the first bar, the second bar, the third bar, and the fourth bar of the first alignment mark, and
the bar of the first alignment mark and the bar of the flipped second alignment mark that belong to the same quadrant are perpendicular to each other.

4. The mark of claim 3, wherein the bar of the first alignment mark and the bar of the flipped second alignment mark that belong to the same quadrant are orthogonal to each other.

5. A wafer bonding method for aligning and bonding a first semiconductor wafer and a flipped second semiconductor wafer, the method comprising:
forming a first alignment mark having a first center of symmetry in a predetermined region of the first semiconductor wafer;
forming a second alignment mark having a second center of symmetry in a predetermined region of the second semiconductor wafer so as to overlap the first alignment mark in a flipped state when the first semiconductor wafer and the flipped second semiconductor wafer are bonded;
aligning the first alignment mark and the second alignment mark; and
bonding the first semiconductor wafer and the second semiconductor wafer,
wherein the first center of symmetry and the second center of symmetry overlap when the first semiconductor wafer and the flipped second semiconductor wafer are aligned,
a difference between the first center of symmetry and the second center of symmetry represents an alignment error between the first semiconductor wafer and the flipped second semiconductor wafer,
the first alignment mark is rotationally symmetrical at 90 degrees and 180 degrees with respect to the first center of symmetry, and is asymmetrical with respect to a first axis passing through the first center of symmetry,
the first alignment mark and the second alignment mark have the same shape and size,
the first alignment mark and the second alignment mark comprises a plurality of bars, and
a bar of the first alignment mark and a bar of the flipped second alignment mark, which belong to the same quadrant among quadrants divided by the first axis and a second axis orthogonal to the first axis, are perpendicular to each other.

6. The method of claim 5, wherein the first alignment mark comprises a first alignment mark element and a third alignment mark element respectively formed in two quadrants arranged diagonally among the quadrants, and a second alignment mark element and a fourth alignment mark element respectively formed in the remaining two quadrants,
the first alignment mark element comprises at least a first bar extending in a direction of the second axis direction,
the second alignment mark element comprises at least a second bar extending in a direction of the first axis direction,
the third alignment mark element comprises at least a third bar extending in a direction of the second axis direction, and
the fourth alignment mark element comprises at least a fourth bar extending in a direction of the first axis direction.

7. The method of claim 6, wherein the second alignment mark comprises a fifth bar, a sixth bar, a seventh bar, and an eighth bar respectively corresponding to the first bar, the second bar, the third bar, and the fourth bar of the first alignment mark, and
the bar of the first alignment mark and the bar of the flipped second alignment mark that belong to the same quadrant are perpendicular to each other.

8. The method of claim 7, wherein the bar of the first alignment mark and the bar of the flipped second alignment mark that belong to the same quadrant are orthogonal to each other.
